(19) United States
(12) Patent Application Publication
(10) Pub. No.: US 2014/0302673 A1
(43) Pub. Date: Oct. 9, 2014

(54) Method of Forming Metal Contacts With Low Contact Resistances in a Group III-N HEMT

(71) Applicant: TEXAS INSTRUMENTS INCORPORATED, Dallas, TX (US)

(72) Inventors: Yoshikazu Kondo, Dallas, TX (US); Shoji Wada, Plano, TX (US); Hiroshi Yamasaki, Richardson, TX (US); Masahiro Iwamoto, Oita-City (JP)

(73) Assignee: Texas Instruments Incorporated, Dallas, TX (US)

(21) Appl. No.: 13/856,043

(22) Filed: Apr. 3, 2013

(51) Int. Cl. H01L 21/283; H01L 21/306

(52) U.S. Cl. CPC H01L 21/283; H01L 21/30621
USPC 438/666

(57) ABSTRACT

Metal contacts with low contact resistances are formed in a group III-N HEMT by forming metal contact openings in the barrier layer of the group III-N HEMT to have depths that correspond to low contact resistances. The metal contact openings are etched in the barrier layer with a first gas combination that etches down into the barrier layer, and a second gas combination that etches further down into the barrier layer.

### RELATED APPLICATIONS

The present invention is related to application Ser. No. ______, (TI-71731) for “Method of Forming Metal Contacts In the Barrier Layer of a Group III-N HEMT” by Yoshikazu Kondo et al filed on an even date herewith, which is hereby incorporated by reference in its entirety.

### BACKGROUND OF THE INVENTION

1. Field of the Invention

The present invention relates to a method of forming metal contacts in a group III-N HEMT and, more particularly, to a method of forming metal contacts with low contact resistances in a group III-N HEMT.

2. Description of the Related Art

Group III-N high electron mobility transistors (HEMTs) have shown potential superiority for power electronics due to their wider bandgap and high electron saturation velocity. These material properties translate into high breakdown voltage, low on-resistance, and fast switching. Group III-N HEMTs can also operate at higher temperatures than silicon-based transistors. These properties make group III-N HEMTs well suited for high-efficiency power regulation applications, such as lighting and vehicular control.

A conventional group III-N HEMT includes a substrate, and a layered structure that is formed on the top surface of the substrate. The layered structure, in turn, includes a buffer layer that touches the substrate, a channel layer that lies over the buffer layer, and a barrier layer that lies over the channel layer. Further, the layered structure can optionally include a cap layer that lies over the barrier layer.

The buffer layer provides a transition layer between the substrate and the channel layer in order to address the difference in lattice constant and to provide a dislocation-minimized growing surface. The channel layer and the barrier layer have different polarization properties and band gaps that induce the formation of a two-dimensional electron gas (2DEG) that lies at the top of the channel layer. The 2DEG, which has a high concentration of electrons, is similar to the channel in a conventional field effect transistor (FET). The cap layer enhances the reliability of the group III-N HEMT.

A conventional group III-N HEMT also includes a metal gate that is formed on the top surface of the layered structure. The metal gate makes a Schottky contact to the barrier layer (or the cap layer if present). Alternately, the metal gate can be isolated from the barrier layer (or the cap layer if present) by an insulating layer.

In addition, a conventional group III-N HEMT includes a source metal contact and a drain metal contact that lies spaced apart from the source metal contact. The source and drain metal contacts, which lie in metal contact openings that extend into the layered structure, make ohmic contacts with the barrier layer.

Native group III-N substrates are not easily available. As a result, group III-N HEMTs commonly use a single-crystal silicon substrate. (Silicon carbide is another common substrate material for group III-N HEMTs.) The layered structure is conventionally grown on the substrate using epitaxial deposition techniques such as metal organic chemical vapor deposition (MOCVD) and molecular beam epitaxy (MBE).

Each of the layers in the layered structure is typically implemented with one or more sequential group-III nitride layers, with the group-III including one or more of In, Ga, and Al. For example, the buffer layer can be implemented with sequential layers of AlN (a thermally-stable material), AlGaN, and GaN. In addition, the channel layer is commonly formed from GaN, while the barrier layer is commonly formed from AlGaN. Further, the cap layer can be formed from GaN.

The source and drain metal contacts are conventionally formed by forming a passivation layer, such as a silicon nitride layer, on the top surface of the layered structure (on the top surface of the cap layer if present, or the top surface of the barrier layer when the cap layer is not present). Following this, a patterned photoresist layer is formed on passivation layer.

After the patterned photoresist layer has been formed, the exposed regions of the passivation layer, the underlying portions of the cap layer (if present), and the underlying portions of the barrier layer are dry etched for a predetermined period of time using a gas combination that includes CHF₃, CF₄, Ar, and O₂.

The dry etch forms source and drain metal contact openings that extend through the passivation layer, through the cap layer (if present), and into the barrier layer. It is very difficult to control the depths of the metal contact openings because the etch is very short, typically a few seconds. As a result, the bottom surface of the metal contact openings frequently extends through the barrier layer and into the channel layer.

After this, a metal layer is deposited to lie over the passivation layer and fill up the metal contact openings. The metal layer is then planarized to expose the top surface of the passivation layer and form source and drain metal contacts in the source and drain metal contact openings, respectively.

### SUMMARY OF THE INVENTION

The present invention provides a method of forming metal contacts with low contact resistances in a high electron mobility transistor. The method includes determining a separation distance between a top surface of a channel layer and a bottom surface of a metal contact that corresponds to a lowest contact resistance. The channel layer lies below and touches a barrier layer. The method also includes etching the barrier layer to form a metal contact opening that has a bottom surface. The bottom surface of the metal contact opening is spaced apart from the top surface of the channel layer by approximately the separation distance.

The present invention also provides an alternate method of forming metal contacts with low contact resistances in metal contact openings in a high electron mobility transistor. The method includes etching a layered structure with a first gas combination to form a number of metal contact openings. The layered structure includes a buffer layer that touches and lies over a substrate, a channel layer that touches and lies over the buffer layer, and a barrier layer that touches and lies over the channel layer. Each of the metal contact openings has a first bottom surface that lies above and spaced apart from a top surface of the channel layer. The method also includes etching the layered structure with a second gas combination to deepen the first bottom surface of each metal contact opening to a second bottom surface that lies below the first bottom surface. The second bottom surface lies above and spaced apart from the top surface of the channel layer by a separation distance. The separation distance lies within a range of 5 Å to 60 Å.

A better understanding of the features and advantages of the present invention will be obtained by reference to the following detailed description and accompanying drawings which set forth an illustrative embodiment in which the principals of the invention are utilized.

### BRIEF DESCRIPTION OF THE DRAWINGS

FIGS. 1-5 are a series of cross-sectional views illustrating an example of a method 100 of forming metal contacts with low contact resistances in a group III-N HEMT in accordance with the present invention.

FIGS. 6A-6D are graphs illustrating examples of the relationship between the separation distance D and the contact resistivity in accordance with the present invention.

### DETAILED DESCRIPTION OF THE INVENTION

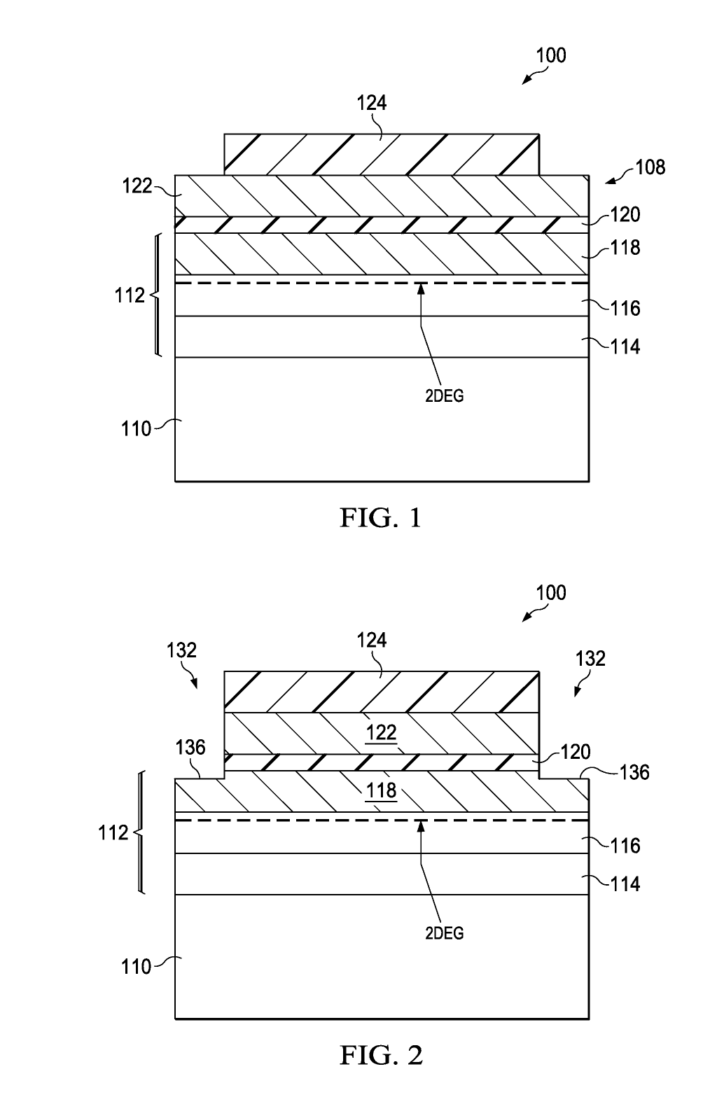

FIGS. 1-5 show a series of cross-sectional views that illustrate an example of a method 100 of forming metal contacts with low contact resistances in a group III-N HEMT in accordance with the present invention. As described in greater detail below, the method of the present invention utilizes a two-step etch process to form metal contacts with low contact resistances in a group III-N HEMT.

As shown in FIG. 1, method 100 utilizes a conventionally-formed group III-N HEMT 108. HEMT 108, in turn, includes a single-crystal, lightly-doped, p-type silicon semiconductor substrate 110 (e.g., <111>), and a layered structure 112 that is formed on the top surface of substrate 110.

Layered structure 112, in turn, includes a buffer layer 114 that touches substrate 110, a channel layer 116 that touches buffer layer 114, and a barrier layer 118 that touches channel layer 116. Further, layered structure 112 can optionally include a cap layer 120 that lies over barrier layer 118.

Buffer layer 114 provides a transition layer between substrate 100 and channel layer 116 as a result of lattice mismatches. Channel layer 116 and barrier layer 118 have different polarization properties and band gaps that induce the formation of a two-dimensional electron gas (2DEG) that lies at the top of channel layer 116. Cap layer 120 provides enhanced reliability.

Each of the layers in layered structure 112 can be implemented with one or more sequential group-III nitride layers, with the group-III including one or more of In, Ga, and Al. For example, buffer layer 114 can be implemented with sequential layers of AlN (a thermally-stable material), AlGaN, and GaN. In addition, channel layer 116 can be formed from GaN, while barrier layer 118 can be formed from AlGaN. Further, cap layer 120 can be formed from GaN.

Further, HEMT 108 includes a passivation layer 122 that touches the top surface of layered structure 112 (on the top surface of cap layer 120 if present, or the top surface of barrier layer 118 when cap layer 120 is not present). Passivation layer 122 can be implemented with, for example, a silicon nitride layer.

As further shown in FIG. 1, method 100 begins by forming a patterned photoresist layer 124 on passivation layer 122. Patterned photoresist layer 124 is formed in a conventional manner, which includes depositing a layer of photoresist, projecting a light through a patterned black/clear glass plate known as a mask to form a patterned image on the layer of photoresist to soften the photoresist regions exposed by the light, and removing the softened photoresist regions.

As shown in FIG. 2, after patterned photoresist layer 124 has been formed, the exposed regions of passivation layer 122, the underlying portions of cap layer 120 (if present), and the underlying portions of barrier layer 118 are dry etched using a gas combination that includes boron trichloride (BCl₃) and sulfur hexafluoride (SF₆) to form source and drain metal contact openings 132.

Each metal contact opening 132 has a bottom surface 136 that lies above and spaced apart from the top surface of channel layer 116. In the present example, the following etch conditions are used:
Pressure: 19 mT-21 mT (preferably 20 mT);
TCP RF: 200 W-400 W (preferably 300 W);
Bias RF: 47.5 W-52.5 W (preferably 50 W);
BCl₃: 20 ccm-30 ccm (preferably 25 ccm);
SF₆: 45 ccm-65 ccm (preferably 55 ccm);
He Clamp: 5 T-10 T (preferably 6 T); and
Temp: 45 deg C.-65 deg C. (preferably 55 C).

The BCl₃ and SF₆ gas combination under the above conditions etches down into barrier layer 118 for a period of time, but then etches substantially no deeper into barrier layer 118 after the period of time. For example, the BCl₃ and SF₆ gas combination under the above preferred conditions etches down into an AlGaN barrier layer 118 to a depth of approximately 43 Å after a period of time of 65 seconds.

However, from 65 seconds to 200 seconds, the BCl₃ and SF₆ gas combination etches substantially no deeper into the AlGaN barrier layer 118. Thus, barrier layer 118 is etched with the BCl₃ and SF₆ gas combination for a predefined time that is equal to or greater than the period of time.

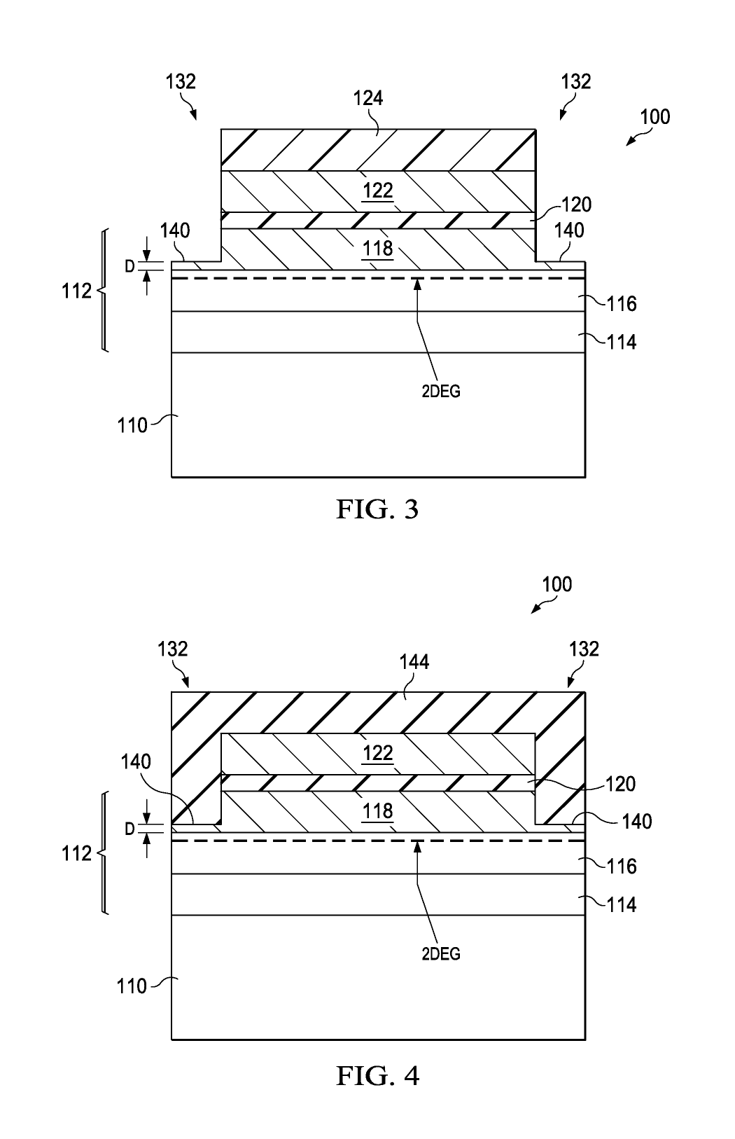

As shown in FIG. 3, after the BCl₃ and SF₆ etch, the gas is changed and the regions of barrier layer 118 exposed by the metal contact openings 132 are dry etched for a predetermined period of time using a gas combination that includes BCl₃ and CL₂ to deepen each bottom surface 136 to a lower bottom surface 140. In the present example, the BCl₃ and CL₂ gas combination etches more of barrier layer 118 than does the BCl₃ and SF₆ gas combination.

Each lower bottom surface 140 lies above and spaced apart from the top surface of channel layer 116 by a separation distance D. After the etch, patterned photoresist layer 124 is removed in a conventional manner, such as with an ash process. In the present example, the following etch conditions are used:
Pressure: 14 mT-16 mT (preferably 15 mT);
TCP RF: 200 W-400 W (preferably 300 W);
Bias RF: 8 W-12 W (preferably 10 W);
BCl₃: 70 ccm-90 ccm (preferably 80 ccm);
Cl₂: 10 ccm-30 ccm (preferably 20 ccm);
He Clamp: 5 T-10 T (preferably 6 T); and
Temp: 45 deg C.-65 deg C. (preferably 55 C).

The BCl₃ and CL₂ gas combination under the above conditions further etches down into barrier layer 118 at a (slow) rate of approximately 1.05 Å/s. Since the initial depths of the metal contact openings 132 in barrier layer 118 are each approximately 43 Å, and since the BCl₃ and CL₂ gas etches down into barrier layer 118 at a rate of approximately 1.05 Å/s, the final depths of the metal contact openings 132 can be precisely controlled.

For example, if barrier layer 118 is 180 Å thick and 43 Å of barrier layer 118 have been removed by the BCl₃ and SF₆ etch, then the BCl₃ and CL₂ etch requires approximately 101.9 seconds at a rate of approximately 1.05 Å/s to extend each metal contact opening 132 down another 107 Å into barrier layer 118, thereby forming the lower bottom surfaces 140 to be 150 Å deep in barrier layer 118 and leaving a 30 Å separation distance D. An approximate etch time of 101.9 seconds is substantially longer than the few etch seconds available in the prior art, thereby allowing precise control of the depths of the metal contact openings 132.

As shown in FIG. 4, after the metal contact openings 132 have been deepened to the lower bottom surfaces 140, a metal layer 144 is deposited to touch the top surface of passivation layer 122 and fill up the metal contact openings 132 in barrier layer 118, cap layer 120, and passivation layer 122. Metal layer 144 is free of gold, and can include, for example, a titanium layer, an aluminum copper layer (0.5% Cu) that touches and lies over the titanium layer, and a titanium nitride cap that touches and lies over the aluminum copper layer.

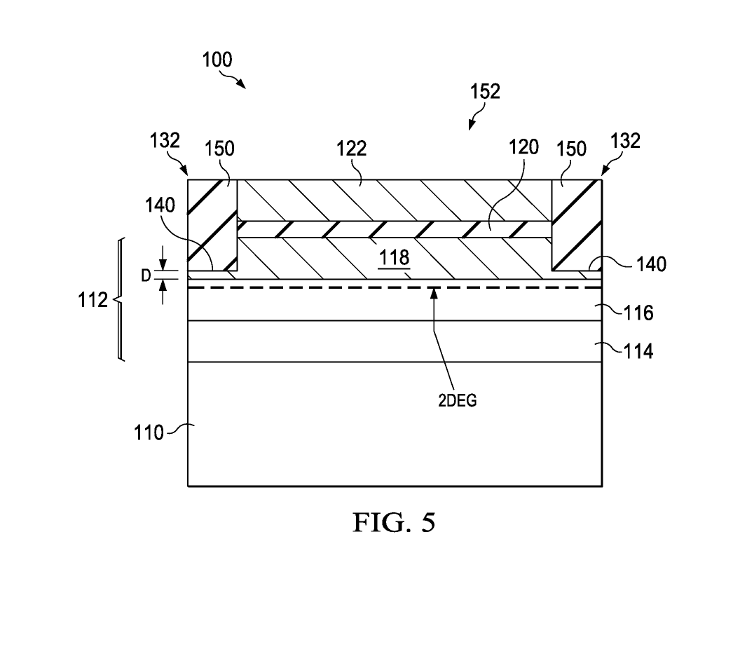

As shown in FIG. 5, after metal layer 144 has been formed, metal layer 144 is planarized in a conventional manner, such as with chemical-mechanical polishing, to expose the top surface of passivation layer 122. The planarization forms source and drain metal contacts 150 in the source and drain metal contact openings 132, respectively. The planarization also forms a group III-N HEMT structure 152. The metal contacts 150 make ohmic connections to barrier layer 118. Method 100 then continues with conventional steps to complete the formation of a group III-N HEMT with metal contacts that have low contact resistances.

The contact resistance of a metal contact 150 is dependent upon the separation distance D, which extends from the top surface of channel layer 116 to the bottom surface of the metal contact 150. The separation distance D is defined by the depths of the metal contact openings 132 in barrier layer 118.

The contact resistance of a metal contact 150 decreases as the BCl₃ and CL₂ etch increases the depths of the metal contact openings 132 and decreases the separation distance D. The decrease in the contact resistance continues until the separation distance D reaches a lowest contact resistance distance.

Once the lowest contact resistance distance has been reached, any further increase in the depths of the metal contact openings 132 and decrease in the separation distance D causes the contact resistance of the metal contact 150 to increase. The extension of a metal contact 150 into channel layer 116 causes a substantial increase in the contact resistance.

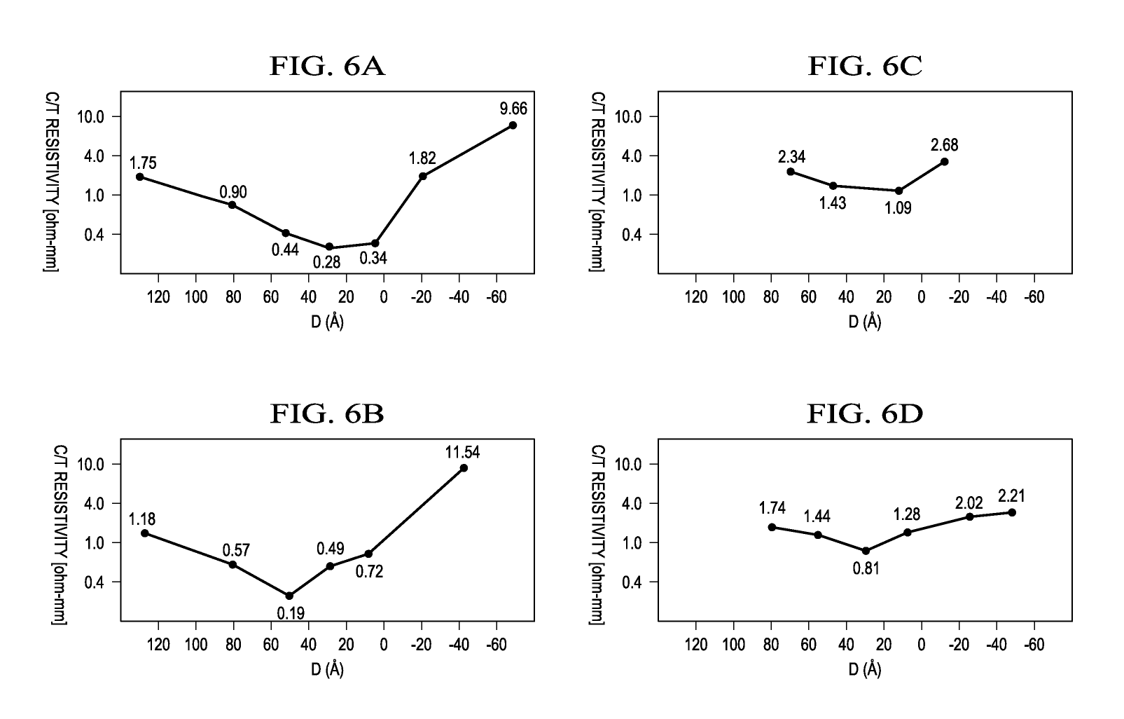

FIGS. 6A-6D show graphs that illustrate examples of the relationship between the separation distance D and the contact resistivity in accordance with the present invention. Equipment variations can cause the separation distance D that corresponds to the lowest contact resistance to vary from machine to machine.

As shown in FIG. 6A, which illustrates the formation of metal contact openings 132 with a first fabrication machine, a separation distance D of approximately 30 Å corresponds with the lowest contact resistance of 0.28 ohm-mm. In addition, a range of separation distances D from approximately 5 Å to 40 Å corresponds with a range of low contact resistances.

The range of low contact resistances extends from the lowest contact resistance of 0.28 ohm-mm to a contact resistance of 0.34 ohm-mm, which is 20% greater than the lowest contact resistance. The contact resistance of 0.34 ohm-mm, which corresponds with a separation distance D of 5 Å or 40 Å, is less than one-quarter of the contact resistance at the top surface of barrier layer 118.

As shown in FIG. 6B, which illustrates the formation of metal contact openings with a second fabrication machine, a separation distance D of approximately 55 Å corresponds with the lowest contact resistance of 0.19 ohm-mm. In addition, a range of separation distances D of approximately 50 Å to 60 Å corresponds with a range of low contact resistances.

The range of low contact resistances extends from the lowest contact resistance of 0.19 ohm-mm to a contact resistance of 0.23 ohm-mm, which is 20% greater than the lowest contact resistance. The contact resistance of 0.23 ohm-mm, which corresponds with a separation distance D of 50 Å or 60 Å, is less than one-quarter of the contact resistance at the top surface of barrier layer 118.

As shown in FIG. 6C, which illustrates the formation of metal contact openings with a third fabrication machine, a separation distance D of approximately 15 Å corresponds with the lowest contact resistance of 1.09 ohm-mm. In addition, a range of separation distances D of approximately 10 Å to 30 Å corresponds with a range of low contact resistances. The range of low contact resistances extends from the lowest contact resistance of 1.09 ohm-mm to a contact resistance of 1.31 ohm-mm, which is 20% greater than the lowest contact resistance.

As shown in FIG. 6D, which illustrates the formation of metal contact openings with a fourth fabrication machine, a separation distance D of approximately 30 Å corresponds with the lowest contact resistance of 0.81 ohm-mm. In addition, a range of separation distances D of approximately 20 Å to 40 Å corresponds with a range of low contact resistances. The range of low contact resistances extends from the lowest contact resistance of 0.81 ohm-mm to a contact resistance of 0.97 ohm-mm, which is 20% greater than the lowest contact resistance.

Thus, in the FIGS. 6A-6D examples, the lowest contact resistance falls within a range of separation distances D of approximately 15 Å to 55 Å. In addition, the range of low contact resistances falls within a range of separation distances D of approximately 5 Å to 60 Å. To obtain the lowest contact resistance, the separation distance D that corresponds with the lowest contact resistance can be determined for the fabrication machine that is to form the metal contact openings.

Thus, the present invention provides a method of forming metal contacts 150 with low contact resistances in a group III-N HEMT. The method first determines the separation distance D between the top surface of channel layer 116 and the bottom surface of a metal contact 150 for a fabrication machine that corresponds to a lowest contact resistance.

Following this, barrier layer 118 is etched to form metal contact openings 132 that each has a bottom surface 140, where the bottom surface of each metal contact opening 132 is spaced apart from the top surface of channel layer 116 by approximately the separation distance D. As described above, the etch is a two-step process that allows the depths of the metal contact openings 132 to be precisely controlled.

In addition, approximately the separation distance is defined to include a range of separation distances that corresponds with a range of low contact resistances, where the range of low contact resistances extends from the lowest contact resistance to a contact resistance that is 20% greater than the lowest contact resistance.

It should be understood that the above descriptions are examples of the present invention, and that various alternatives of the invention described herein may be employed in practicing the invention. For example, group III-N HEMTs are conventionally formed as depletion-mode devices, but can also be formed as enhancement-mode devices.

The present invention applies equally well to enhancement-mode devices as the substrate and buffer layer structures of these devices are the same. Therefore, it is intended that the following claims define the scope of the invention and that structures and methods within the scope of these claims and their equivalents be covered thereby.

What is claimed is:

1. A method of forming a high electron mobility transistor comprising:
determining a separation distance between a top surface of a channel layer and a bottom surface of a metal contact that corresponds to a lowest contact resistance, the channel layer lying below and touching a barrier layer; and
etching the barrier layer to form a metal contact opening that has a bottom surface, the bottom surface of the metal contact opening being spaced apart from the top surface of the channel layer by approximately the separation distance.

2. The method of claim 1 wherein approximately the separation distance includes a range of separation distances that corresponds with a range of low contact resistances, the range of low contact resistances extending from the lowest contact resistance to a contact resistance that is 20% greater than the lowest contact resistance.

3. The method of claim 1 wherein etching the barrier layer includes:
etching the barrier layer with a first gas combination to form the metal contact opening with a bottom that lies above and spaced apart from the top surface of the channel layer; and
etching the barrier layer with a second gas combination to deepen the bottom of the metal contact opening to form the bottom surface of the metal contact opening.

4. The method of claim 3 wherein the first gas combination etches the barrier layer to a depth for a period of time, and substantially no deeper after the period of time.

5. The method of claim 4 wherein the barrier layer is etched with the first gas combination for a predefined time that is equal to or greater than the period of time.

6. The method of claim 5 wherein the second gas combination etches more of the barrier layer than does the first gas combination.

7. The method of claim 5 wherein the first gas combination includes boron trichloride (BCl₃) and sulfur hexafluoride (SF₆).

8. The method of claim 7 wherein the second gas combination includes boron trichloride (BCl₃) and chlorine (Cl₂).

9. The method of claim 1 wherein the separation distance is determined for a fabrication machine.

10. The method of claim 1 and further comprising:
depositing a metal contact layer that touches the bottom surface and fills up the metal contact opening; and
planarizing the metal contact layer to form a metal contact that lies in the metal contact opening and touches the barrier layer.

11. A method of forming a high electron mobility transistor comprising:
etching a layered structure with a first gas combination to form a number of metal contact openings, the layered structure including a buffer layer that touches and lies over a substrate, a channel layer that touches and lies over the buffer layer, and a barrier layer that touches and lies over the channel layer, each of the metal contact openings having a first bottom surface that lies above and spaced apart from a top surface of the channel layer; and
etching the layered structure with a second gas combination to deepen the first bottom surface of each metal contact opening to a second bottom surface that lies below the first bottom surface, the second bottom surface lying above and spaced apart from the top surface of the channel layer by a separation distance, the separation distance lying within a range of 5 Å to 60 Å.

12. The method of claim 11 wherein the first gas combination etches the barrier layer to a depth for a period of time, and substantially no deeper after the period of time.

13. The method of claim 12 wherein the barrier layer is etched with the first gas combination for a predefined time that is equal to or greater than the period of time.

14. The method of claim 13 wherein the barrier layer is etched with the second gas combination for a predetermined period of time.

15. The method of claim 14 wherein the first gas combination includes boron trichloride (BCl₃) and sulfur hexafluoride (SF₆).

16. The method of claim 15 wherein the second gas combination includes boron trichloride (BCl₃) and chlorine (Cl₂).

17. The method of claim 11 wherein the second gas combination etches more of the barrier layer than does the first gas combination.

18. The method of claim 11 wherein the first gas combination also etches through a cap layer that touches and lies above the barrier layer, and through a passivation layer that touches and lies above the cap layer, the cap layer including GaN, the passivation layer including silicon nitride.

19. The method of claim 11 and further comprising depositing a metal contact layer that touches each second bottom surface and fills up the metal contact openings.

20. The method of claim 19 and further comprising planarizing the metal contact layer to form a number of spaced-apart metal contacts that lie in the number of metal contact openings, and touch the barrier layer.
